(19) United States
(12) Patent Application Publication
(10) Pub. No.: US 2015/0137739 A1
(43) Pub. Date: May 21, 2015

(54) CHARGING SYSTEM, CHARGING SYSTEM CONTROL METHOD, AND CONTROL PROGRAM

(71) Applicant: NEC Corporation, Tokyo (JP)

(72) Inventor: Takayuki Shizuno, Tokyo (JP)

(73) Assignee: NEC Corporation, Tokyo (JP)

(21) Appl. No.: 14/401,646

(22) PCT Filed: May 29, 2013
(86) PCT No.: PCT/JP2013/064896

§ 371 Date: Nov. 17, 2014

(30) Foreign Application Priority Data
Jun. 1, 2012 (JP) 2012-126287

(51) Int. Cl. H02J 7/00; G01R 31/36

(52) U.S. Cl. CPC H02J 7/007; G01R 31/3648; G01R 31/3606
USPC 320/107; 320/137

(57) ABSTRACT

[Problems] To minimize an electric power loss of an entire charging system.

[Means for solving the problems] An operation combination determination unit 145 selects a case of which a charger's electric power consumption is between a charger's maximum electric power consumption and a charger's minimum electric power consumption from a database 146, selects a table corresponding to a remaining amount of a storage battery for each case selected above, and determines a combination of operations of a charger 150, an AC/DC converter 110, and a DC/DC converter 120 in the selected table so that a loss level of an entire charging system 100 is minimum. An operation control unit 147 operates the charger 150, the AC/DC converter 110, and the DC/DC converter 120 based on the combination determined by the operation combination determination unit 145.

### TECHNICAL FIELD

The present invention relates to a charging system, a charging system control method, and a control program and in particular, relates to a charging system which minimizes an electric power loss when charging an electric vehicle, a charging system control method, and a control program.

### BACKGROUND ART

In recent years, an electric vehicle in which an engine is not mounted and which travels by using only an electric motor is being developed. A storage battery is mounted in this electric vehicle. When such electric vehicle travels, an electricity storage amount stored in the storage battery decreases and the storage battery needs to be charged by using a charging facility installed in an urban area, a home garage, or the like.

With regard to charging the storage battery mounted in the electric vehicle, there are problems such as a reduction in charge time, a reduction in electric power loss, and the like. In order to solve these problems, various prior arts are proposed.

For example, in PTL1, charge means in which another built-in storage battery is provided in the charging system, the another built-in storage battery is charged in advance before charging the storage battery that is a charged object, and when the storage battery that is the charged object is charged, the storage battery that is the charged object is rapidly charged with a large electric power by using the electric power of the built-in storage battery in addition to an electric power from an external electric power source is disclosed. Because the built-in storage battery is provided in the charging system, even when a capacity of the external electric power source is small, the storage battery can be rapidly charged with a large electric power.

In PTL2, means in which a built-in storage battery is provided in an electric power source system and which select either the external electric power source or the built-in storage battery based on the electric power loss of the electric power source system when the electric power is supplied to a load are disclosed. The electric power can be supplied while saving energy by reducing the electric power loss generated by charging and discharging of an AC/DC converter and the built-in storage battery included in the electric power source system. This method uses a characteristic in which generally, an electric power conversion efficiency of an AC/DC converter and a DC/DC converter is high when the load is heavy and an electric power conversion efficiency is low when the load is light.

### CITATION LIST

### Patent Literature

### [PTL 1]

Japanese Patent Application Laid-Open No. 2011-259572

### [PTL 2]

Japanese Patent Application Laid-Open No. 2011-151952

### SUMMARY OF INVENTION

### Technical Problem

A charging system in which the means disclosed in PTL1 and the means disclosed in PTL2 are combined will be analyzed below. A charger having an electric-vehicle-specific charge interface is connected as a load and the charging system charges the electric vehicle. The charging system rapidly charges the electric vehicle with a large electric power by using the electric power of the built-in storage battery in addition to the electric power from the external electric power source so as to supply the electric power required by the electric vehicle. At this time, the electric power loss of a DC/DC converter that is generated by charging and discharging of the built-in storage battery included and an AC/DC converter in the charging system is taken into consideration. Therefore, at a time of start of charging the electric vehicle at which the large electric power is needed and even at a time near the end of charging at which the small electric power is enough, there is a possibility that the electric power loss can be suppressed.

However, although the electric power loss of the AC/DC converter and the DC/DC converter is taken into consideration, the electric power loss of the charger is not taken into consideration. Therefore, in the entire charging system, the unexpected electric power loss may occur.

Namely, because the characteristic of the AC/DC converter and the DC/DC converter is different from that of the charger, there may be a case in which the electric power loss estimated by using a conventional technology is different from the electric power loss actually occurred.

A charging system actually used includes a plurality of AC/DC converters, a plurality of DC/DC converters, a plurality of the storage batteries, and a plurality of the charges, and because a system is complicated, a possibility that the unexpected electric power loss occurs increases.

By the way, generally, the electric power consumption of the charger having the electric-vehicle-specific charge interface can be controlled within a fixed range. In the invention disclosed in PTL1 and PTL2, this characteristic of the charger is not taken into consideration.

An object of the present invention is to solve the above-mentioned problem and provide a charging system, a charging system control method, and a control program which can minimize an electric power loss generated in the entire charging system.

### Solution to Problem

The present invention which solves the above-mentioned problem is a charging system comprising a charger, an AC/DC converter, a DC/DC converter, a storage battery, and a control device, and the control device includes a charger's required electric power consumption grasping unit that grasps a required electric power consumption of the charger, a charger's maximum electric power consumption calculation unit that calculates a maximum electric power consumption of the charger based on the required electric power consumption, a charger's minimum electric power consumption calculation unit that calculates a minimum electric power consumption of the charger based on the required electric power consumption, a storage battery remaining capacity grasping unit that grasps a remaining capacity of the storage battery, an operation combination determination unit that determines a combination of operations of the charger, the AC/DC converter, and the DC/DC converter based on the remaining capacity of the storage battery so that an electric power loss of the entire charging system is minimum when the electric power consumption of the charger is between the charger's maximum electric power consumption and the charger's minimum electric power consumption, and an operation control unit that operates the charger, the AC/DC converter, and the DC/DC converter based on the combination.

The present invention which solves the above-mentioned problem is a method for controlling a charging system comprising a charger, an AC/DC converter, a storage battery, a DC/DC converter, and a control device, and the control device includes the steps of: grasping a required electric power consumption of the charger, calculating a maximum electric power consumption of the charger based on the required electric power consumption, calculating a minimum electric power consumption of the charger based on the required electric power consumption, grasping a remaining capacity of the storage battery, determining a combination of operations of the charger, the AC/DC converter, and the DC/DC converter based on the remaining capacity of the storage battery so that an electric power loss of the entire charging system is minimum when the electric power consumption of the charger is between the charger's maximum electric power consumption and the charger's minimum electric power consumption, and operating the charger, the AC/DC converter, and the DC/DC converter based on the combination.

The present invention which solves the above-mentioned problem is a control program for controlling a charging system comprising a charger, an AC/DC converter, a storage battery, a DC/DC converter, and a control device, and the control program causes the control device to perform a charger's required electric power consumption grasping process in which a required electric power consumption of the charger is grasped, a charger's maximum electric power consumption calculation process in which a maximum electric power consumption of the charge is calculated based on the required electric power consumption, a charger's minimum electric power consumption calculation process in which a minimum electric power consumption of the charger is calculated based on the required electric power consumption, a storage battery remaining capacity grasping process in which a remaining capacity of the storage battery is grasped, an operation combination determination process in which a combination of operations of the charger, the AC/DC converter, and the DC/DC converter is determined based on the remaining capacity of the storage battery so that an electric power loss of the entire charging system is minimum when the electric power consumption of the charger is between the charger's maximum electric power consumption and the charger's minimum electric power consumption, and an operation control process in which the charger, the AC/DC converter, and the DC/DC converter are operated based on the combination.

### Advantageous Effects of Invention

According to the present invention, the electric power loss of the entire charging system can be minimized.

### BRIEF DESCRIPTION OF DRAWINGS

FIG. 1 is a brief configuration diagram of a charging system.

FIG. 2 shows a brief configuration and a functional block diagram of an electric power control device.

FIG. 3 shows a data structure of a database.

FIG. 4 shows a structure of a table.

FIG. 5 is a flowchart showing a content of a process performed by an electric power control device.

FIG. 6 shows a brief configuration and a functional block diagram of an electric power control device (modification example).

FIG. 7 shows a brief configuration and a functional block diagram of an electric power control device (modification example).

### DESCRIPTION OF EMBODIMENTS

—Summary—

The present invention is a charging system comprising a charger, an AC/DC converter, a DC/DC converter, a storage battery, and a control device, and the control device is equipped with a charger's required electric power consumption grasping unit that grasps a required electric power consumption of the charger, a charger's maximum electric power consumption calculation unit that calculates a maximum electric power consumption of the charger based on the required electric power consumption, a charger's minimum electric power consumption calculation unit that calculates a minimum electric power consumption of the charger based on the required electric power consumption, a storage battery remaining capacity grasping unit that grasps a remaining capacity of the storage battery, an operation combination determination unit that determines a combination of operations of the charger, the AC/DC converter, and the DC/DC converter based on the remaining capacity of the storage battery so that an electric power loss of the entire charging system is minimum when the electric power consumption of the charger is between the charger's maximum electric power consumption and the charger's minimum electric power consumption, and an operation control unit that operates the charger, the AC/DC converter, and the DC/DC converter based on the combination.

This invention is focusing on a characteristics that the electric power consumption of the charger can be adjusted between the maximum electric power consumption and the minimum electric power consumption (including the maximum and the minimum). Accordingly, the most suitable combination of operations can be selected from among many candidates. The electric power loss of the charger is taken into consideration at the combination of operation. Whereby, the electric power loss of the entire charging system can be minimized.

In the present invention, it is further preferable that the above-mentioned control device is further equipped with a combination storage unit that stores a set of the combinations and the operation combination determination unit refers to the set of the combinations and determines the combination of the operations.

The charger is equipped with an electric-vehicle-specific charge interface. Because the electric power consumption of such charger is stable within a fixed range between the maximum electric power consumption and the minimum electric power consumption, the set of the combinations of the operations can be created as a table, for example, and stored in advance. By using this, the combination of the operations can be easily determined so that the electric power loss of the entire charging system is minimized.

In the present invention, it is further preferable that the above-mentioned control device is further equipped with an actual measurement value grasping unit that grasps an actual measurement value that is a result obtained by the operations of the charger, the AC/DC converter, and the DC/DC converter and the above-mentioned combination storage unit rewrites the set of the combinations based on the actual measurement value.

By reflecting the actual measurement value, the reliability of control is improved.

In the present invention, it is further preferable that the above-mentioned operation combination determination unit determines the combination with that the AC/DC converter operates so as to charge and discharge the storage battery at an electric power smaller than a rated electric power.

Next, an exemplary embodiment of the present invention will be described in detail with reference to the drawing.

—Configuration—

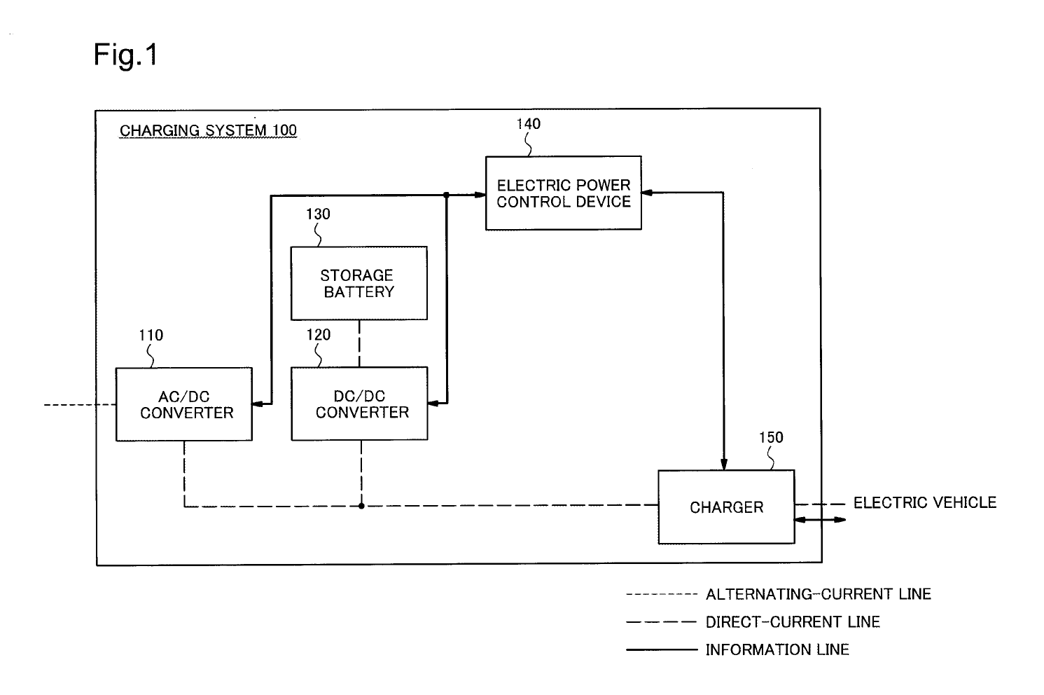

FIG. 1 is a brief configuration diagram of a charging system 100 according to the exemplary embodiment of the present invention. The charging system 100 is equipped with an AC/DC converter 110, a DC/DC converter 120, a storage battery 130, an electric power control device 140, and a charger 150. In FIG. 1, one AC/DC converter 110, one DC/DC converter 120, one storage battery 130, and one charger 150 are illustrated. However, the number of these elements is not limited to one.

The AC/DC converter 110 converts an alternating current into a direct current. When an electric power received from an external alternating-current power source is supplied to a direct-current line, the AC/DC converter 110 operates so as to supply the electric power set by the electric power control device 140. The setting of the electric power is notified from the electric power control device 140.

The DC/DC converter 120 converts the direct current of a certain voltage into the direct current of another voltage. When the electric power discharged by the storage battery 130 is supplied to the direct-current line, the DC/DC converter 120 operates so as to supply the electric power set by the electric power control device 140. Further, when the storage battery 130 receives the electric power for charging from the direct-current line, the DC/DC converter 120 operates so as to receive the electric power set by the electric power control device 140. The setting of the electric power is notified from the electric power control device 140. Further, the DC/DC converter 120 notifies the electric power control device 140 of the remaining capacity of the storage battery 130.

The storage battery 130 is a secondary battery such as a lithium ion battery or the like.

The charger 150 is a charger which is equipped with the electric-vehicle-specific charge interface. The charger 150 transmits/receives information about charging to/from the electric vehicle and also supplies the electric power to the electric vehicle. The information transmitted to/received from the electric vehicle is for example a required electric power of the electric vehicle, a required electric power amount, a requested charging time, or the like. The charger 150 includes a human interface for a person who charges the electric vehicle. The human interface transmits and receives information such as for example, authentication information, billing information, or the like. The charger 150 is electrically equivalent to the DC/DC converter 120. When the electric power received from the direct-current line in the charging system 100 is supplied to the electric vehicle, the charger 150 operates so as to supply the electric power set by the electric power control device 140 to the electric vehicle. A setting of the electric power is transmitted from the electric power control device 140. Further, the charger 150 notifies the electric power control device 140 of the required electric power.

The electric power control device 140 communicates with the AC/DC converter 110, the DC/DC converter 120, and the charger 150 via an information line. Contents of the communication are the information on setting the electric power to the AC/DC converter 110, the DC/DC converter 120, and the charger 150. Further, the electric power control device 140 receives the remaining capacity of the storage battery 130 from the DC/DC converter 120. Furthermore, the electric power control device 140 receives the required electric power or the like from the charger 150. Though a power supply is not shown in FIG. 1, the power supply is also connected to the electric power control device 140.

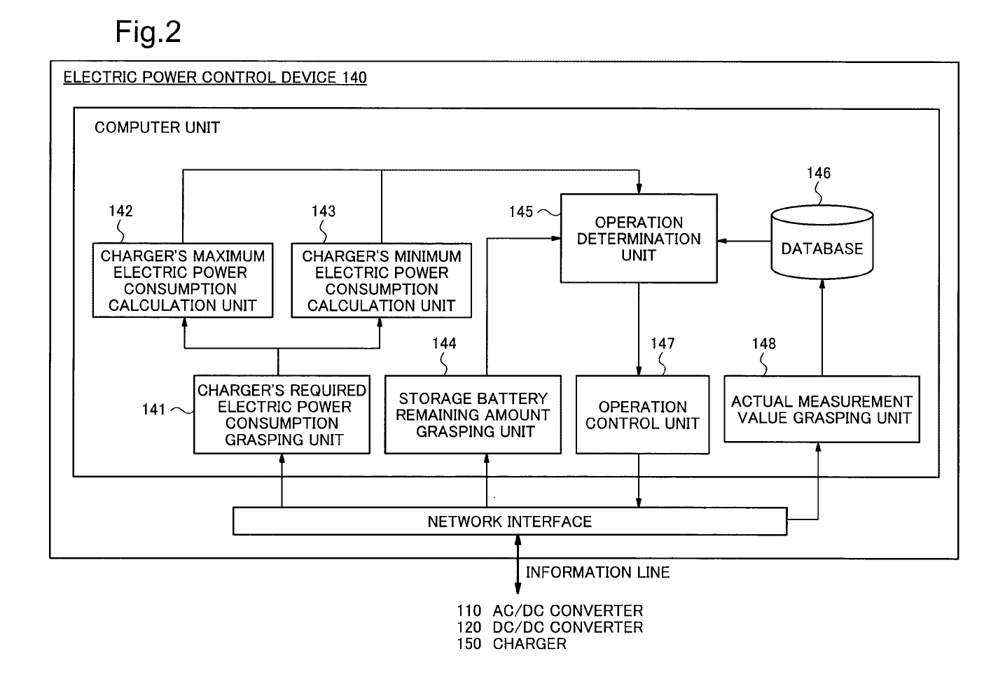

FIG. 2 shows a brief configuration and a functional block diagram of the electric power control device 140. The electric power control device 140 is equipped with a network interface and a computer unit. The electric power control device 140 communicates with the AC/DC converter 110, the DC/DC converter 120, and the charger 150 through the network interface. The computer unit is a main portion of a computer composed of a CPU, a RAM, an OS, and the like. The computer unit contains a charger's required electric power consumption grasping unit 141, a charger's maximum electric power consumption calculation unit 142, a charger's minimum electric power consumption calculation unit 143, a storage battery remaining capacity grasping unit 144, an operation combination determination unit 145, a database 146, an operation control unit 147, and an actual measurement value grasping unit 148.

The electric power consumption of the charger 150 can be adjusted between the maximum electric power consumption and the minimum electric power consumption (including the maximum electric power consumption and the minimum electric power consumption) and this characteristic is used in the present invention.

The charger's required electric power consumption grasping unit 141 grasps the required electric power consumption of the charger 150 based on the information transmitted from the charger 150.

The charger's maximum electric power consumption calculation unit 142 calculates the maximum electric power consumption of the charger 150 based on the charger's required electric power consumption. For example, the charger's maximum electric power consumption calculation unit 142 calculates the maximum electric power consumption of the charger 150 according to the maximum value of the electric power required by the electric vehicle.

The charger's minimum electric power consumption calculation unit 143 calculates the minimum electric power consumption of the charger 150 based on the charger's required electric power consumption. In the charging of the electric vehicle, there is a case in which the required electric power consumption of the charger 150 can be reduced irrespective of a request from the electric vehicle. The minimum value of the required electric power consumption of the charger 150 is determined according to the minimum electric power of the charger 150 or a type of the electric vehicle (explained in detail in modification example).

Further, because the electric power consumption of the charger 150 which includes the electric-vehicle-specific charge interface is within a fixed range between the maximum electric power consumption and the minimum electric power consumption and stable, a database (described later) can be created in advance.

The storage battery remaining capacity grasping unit 144 acquires the remaining capacity of the storage battery 130 from the storage battery 130 directly or via the DC/DC converter 120 and grasps the remaining capacity of the storage battery 130.

The operation combination determination unit 145 determines the combination of the operations of the charger 150, the AC/DC converter 110, and the DC/DC converter 120 based on the remaining capacity of the storage battery so that the electric power loss of the entire charging system 100 is minimum (the conversion efficiency is maximum) when the electric power consumption of the charger 150 is between the charger's maximum electric power consumption and the charger's minimum electric power consumption (including the maximum electric power consumption and the minimum electric power consumption).

The database 146 stores the set of the combinations of the operations of the charger 150, the AC/DC converter 110, and the DC/DC converter 120 for each remaining capacity of the storage battery and each charger's electric power consumption as a table.

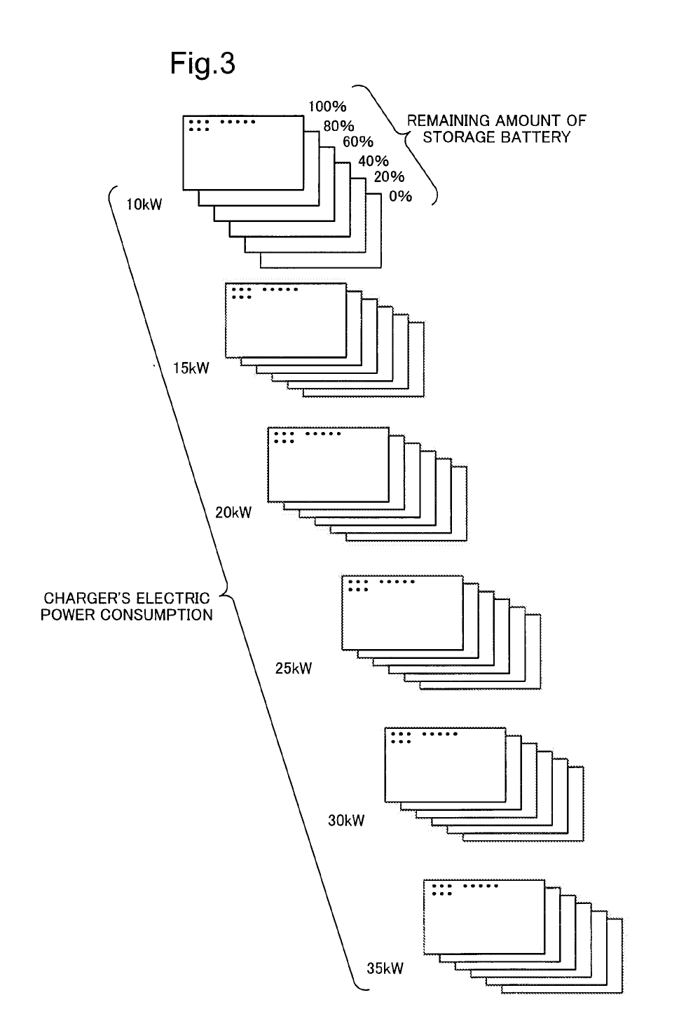

FIG. 3 shows a conceptual rendering of the data structure of the database 146. Further, for convenience of explanation, FIG. 3 is simplified.

In an example shown in FIG. 3, the charger's electric power consumption is classified into six cases, of which the charger's electric power consumption are 10 kW, 15 kW, 20 kW, 25 kW, 30 kW, and 35 kW. Further, for each of six cases, the remaining capacity of the storage battery is classified into six cases, of which the remaining capacity of the storage battery are 0%, 20%, 40%, 60%, 80%, and 100% and a table is created for each of the cases of which the remaining capacity of the storage battery are 0%, 20%, 40%, 60%, 80%, and 100%.

Further, when the characteristics of the AC/DC converter 110, the DC/DC converter 120, and the charger 150 vary with an external factor such as a temperature or the like, the table may be created for each value of the external factor.

The operation combination determination unit 145 selects a case of which the charger's electric power consumption is between the charger's maximum electric power consumption and the charger's minimum electric power consumption (including the maximum electric power consumption and the minimum electric power consumption) from the database 146 and selects the table corresponding to the remaining capacity of the storage battery for each case. For example, when it is calculated that the maximum charger electric power consumption is 30 kW and the minimum charger electric power consumption is 20 kW, the operation combination determination unit 145 selects the following three cases: a case of which the charger's electric power consumption is 20 kW, a case of which the charger's electric power consumption is 25 kW, and a case of which the charger's electric power consumption is 30 kW. When the remaining capacity of the storage battery is 80%, the operation combination determination unit 145 selects a table corresponding to a case of which the remaining capacity of the storage battery is 80% for each of the above-mentioned three cases. Namely, three tables are selected.

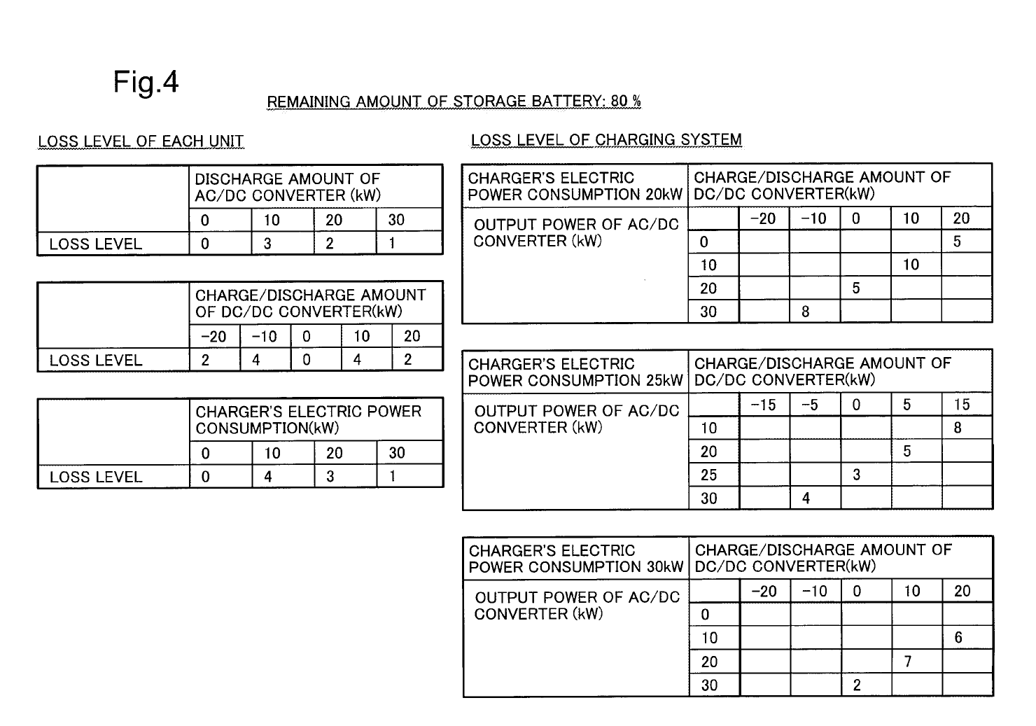

FIG. 4 shows a conceptual rendering of a structure of the table. Further, for convenience of explanation, FIG. 4 is simplified.

In the left part of FIG. 4, the electric power losses related to conversion efficiencies of the AC/DC converter 110, the DC/DC converter 120, and the charger 150 are shown as a loss level (dimensionless value). For example, when the electric power of 20 kW is discharged in the AC/DC converter 110, the loss level is 2. When the electric power of 10 kW is charged in the DC/DC converter 120, the loss level is 4.

Further, for convenience of explanation, the loss level is used as the electric power loss related to the conversion efficiency. However, a percentage of the electric power loss or the reciprocal of the conversion efficiency may be used.

The table shown in the right part of FIG. 4 indicates the set of the combinations of the operations of the AC/DC converter 110, the DC/DC converter 120, and the charger 150. This table shows the loss level (dimensionless value) of the entire charging system 100. For example, when the electric power discharged by the AC/DC converter 110 is 30 kW and the electric power charged by the DC/DC converter 120 is 10 kW, the electric power that can be consumed by the charger 150 is 20 kW (=30−10) and the loss level is 8.

The loss level (dimensionless value) of the entire charging system 100 is calculated based on the loss levels of the AC/DC converter 110, the DC/DC converter 120, and the charger 150. For example, in the above-mentioned example, when the electric power discharged by the AC/DC converter 110 is 30 kW, the loss level is 1. When the electric power charged by the DC/DC converter 120 is 10 kW, the loss level is 4. When the electric power consumption of the charger 150 is 20 kW, the loss level is 3. Accordingly, the loss level of the entire charging system 100 is 8 (=1+4+3).

Further, for convenience of explanation, in FIG. 3 and FIG. 4, an interval between discrete values is large. However, when the interval between discrete values is small, control can be accurately performed. A map using a continuous value can be used instead of the table using the discrete value.

The operation combination determination unit 145 determines the combination of the operations of the charger 150, the AC/DC converter 110, and the DC/DC converter 120 in the selected table so that the loss level of the entire charging system 100 is minimum.

The operation control unit 147 operates the charger 150, the AC/DC converter 110, and the DC/DC converter 120 based on the combination determined by the operation combination determination unit 145. For example, when the operation combination determination unit 145 determines that the AC/DC converter 110 discharges the electric power of 30 kW, the DC/DC converter 120 charges and discharges the electric power of 0 kW, and the charger 150 consumes the electric power of 30 kW (=30+−0) and the loss level of this combination is 2 and minimum, the operation control unit 147 operates the AC/DC converter 110, the DC/DC converter 120, and the charger 150 so that the electric power of 30 kW is discharged by the AC/DC converter 110, the electric power of 0 kW is charged and discharged by the DC/DC converter 120, and the electric power of 30 kW is consumed by the charger 150.

The actual measurement value grasping unit 148 acquires and grasps the actual measurement value of the electric power loss related to the conversion efficiency from the AC/DC converter 110, the DC/DC converter 120, and the charger 150. Further, the actual measurement value grasping unit 148 converts the actual measurement value of the electric power loss into the loss level (dimensionless value) and updates the database 146 by using the loss level.

—Operation—

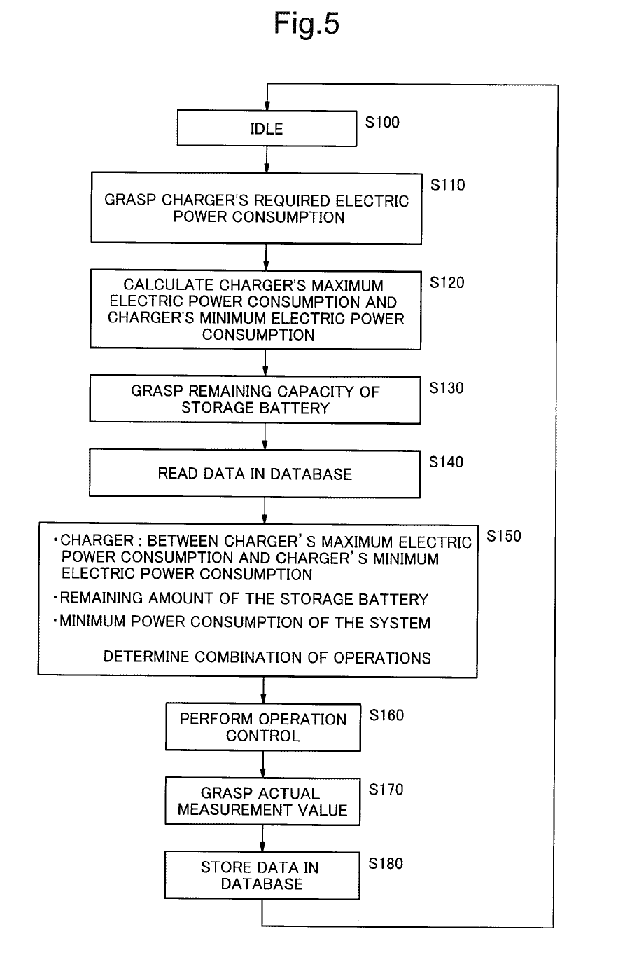

FIG. 5 is a flowchart showing a content of a process performed by the electric power control device 140. Each process shown in the flowchart is realized by executing a program stored in the computer unit. The operation of the charging system 100 will be described by using the flowchart.

An initial state of the electric power control device 140 is an idle state (S100). The electric power control device 140 periodically grasps the required electric power consumption of the charger 150 since the idle state (S110). The charger 150 notifies the electric power control device 140 of the required electric power consumption. The charger 150 transmits this information at a time judged by the charger 150 or at a time at which communicating with the electric power control device 140 is performed.

Next, the electric power control device 140 calculates the maximum electric power consumption and the minimum electric power consumption of the charger 150 based on the required electric power consumption (S120).

On the other hand, the electric power control device 140 grasps the remaining capacity of the storage battery 130 (S130). The storage battery 130 notifies the electric power control device 140 of the remaining capacity of the storage battery directly or via the DC/DC converter 120. This notification may be performed by the storage battery 130 or the DC/DC converter 120 at a time judged by the storage battery 130 or the DC/DC converter 120 or at a time at which communicating with the electric power control device 140 is performed.

After grasping the maximum electric power consumption and the minimum electric power consumption of the charger 150 and the remaining capacity of the storage battery 130, the electric power control device 140 accesses the database 146 (S140).

First, the electric power control device 140 selects a case of which the charger's electric power consumption is between the maximum electric power consumption and the minimum electric power consumption from the database 146. Further, the electric power control device 140 selects the table corresponding to the grasped remaining capacity of the storage battery for each case selected. The electric power control device 140 determines the combination of the operations of the charger 150, the AC/DC converter 110, and the DC/DC converter 120 from among the selected tables so that the loss level of the entire charging system 100 is minimum (S150).

The electric power control device 140 notifies the AC/DC converter 110, the DC/DC converter 120, and the charger 150 of the determined combination of operations and the electric power facilities 110, 120, and 150 operate at the electric power specified by the electric power control device 140 (S160).

The AC/DC converter 110, the DC/DC converter 120, and the charger 150 operate and notify the electric power control device 140 of the actual measurement value of the electric power loss related to the conversion efficiency. The electric power control device 140 grasps the actual measurement value (S170). Further, the electric power control device 140 converts the actual measurement value of the electric power loss into the loss level and updates the database 146 by using the dimensionless value (S180).

When the electric power control device 140 performs a series of processes, the state of the electric power control device 140 returns to the idle state (S100).

—Effect—

In the conventional technology, control is performed based on an assumption that a general characteristic in which when the charger's electric power consumption is large, the loss level is small and when the charger's electric power consumption is small, the loss level is large appears. However, the electric power loss of the charger 150 is not taken into consideration in the conventional technology. Therefore, the unexpected electric power loss may occur in the entire charging system 100. Namely, this control is not necessarily the most suitable one.

In this exemplary embodiment, the combination of the operations of the electric power facilities 110, 120, and 150 is determined so that the loss level of the entire charging system 100 is minimum by taking the electric power loss of the charger 150 into consideration. As a result, the most suitable control by which the loss level of the entire charging system 100 is minimized can be performed.

For example, in a case where there is a combination of the operations with which the loss level of the entire charging system 100 is reduced when the charger's electric power consumption is set to an electric power smaller than the maximum electric power consumption, its combination of the operations is selected.

Further, in the conventional technology, a control by which the storage battery is charged and discharged at the rated electric power is performed. Namely, it is controlled whether or not the storage battery is charged and whether or not the storage battery is discharged. As a result, the unexpected electric power loss may occur.

In this exemplary embodiment, in a case where there is a combination with which the loss level of the entire charging system 100 is reduced when the storage battery 130 is discharged at an electric power smaller than the rated electric power, this combination of the operations is selected.

For example, even in a case where the remaining capacity of the storage battery 130 is 40%, there is a possibility that the loss level of the entire charging system 100 decreases when the storage battery 130 is continuously discharged at an electric power smaller than the rated electric power without stopping discharging.

Further, in a case where there is a combination with which the loss level of the entire charging system 100 is reduced when the storage battery 130 is charged at an electric power smaller than the rated electric power, this combination of the operations is selected.

For example, even in a case where the remaining capacity of the storage battery 130 is 80%, there is a possibility that the loss level of the entire charging system 100 decreases when the storage battery 130 is continuously charged at an electric power smaller than the rated electric power without stopping charging.

Thus, by determining the combination of the operations based on the table created by taking the characteristics of the electric power facilities 110, 120, 130, and 150 into consideration, the most suitable control by which the loss level of the entire charging system 100 is minimized can be performed.

The exemplary embodiment is characterized by calculating the maximum electric power consumption and the minimum electric power consumption of the charger 150. A range between the maximum electric power consumption and the minimum electric power consumption is a fixed range and stable. As a result, the database storing the table can be created in advance.

The exemplary embodiment is characterized in that the electric power consumption of the charger 150 can be adjusted between the maximum electric power consumption and the minimum electric power consumption. As a result, a plurality of tables is selected and the most suitable combination of the operations can be determined from among many candidates.

The exemplary embodiment is characterized in that the actual measurement value of the loss level is grasped and the database 146 is rewritten. As a result, the database 146 is always updated with the latest information and the reliability of control is improved.

### Modification Example

The invention of the present application is not limited to the above-mentioned exemplary embodiment and the various modifications can be made within the scope of the technical concept of the invention of the present application. An example of the modification will be described.

1. Generally, if an electric vehicle cannot be charged within a desired period of time, a charging system is not practically used. The charger 150 is a charge interface and acquires the required electric power amount from the electric vehicle. Further, the charger 150 is an interface with a human and acquires the requested charging time.

The charger's required electric power consumption grasping unit 141 grasps the required electric power consumption based on the required electric power amount and the requested charging time.

The charger's minimum electric power consumption calculation unit 143 takes the requested charging time into consideration and calculates the minimum electric power consumption of the charger 150 based on the charger's required electric power consumption.

Configuration and operation excluding those mentioned above are the same as those of the above-mentioned exemplary embodiment.

As a result, the most suitable control by which the loss level of the entire charging system 100 is minimized while ensuring that the charging of the electric vehicle is completed within the requested charging time can be performed.

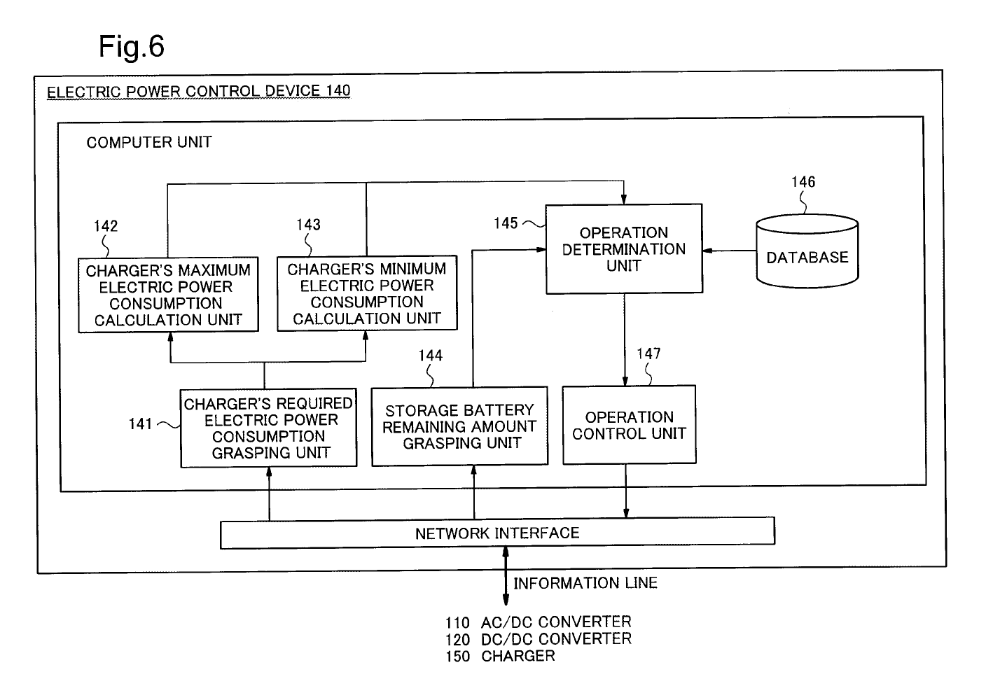

2. In the above-mentioned exemplary embodiment, the actual measurement value grasping unit 148 and the processes of steps S170 and S180 shown in the flowchart are not necessarily required. When this unit is not used and these processes are not performed, an effect in which the reliability of control is improved cannot be obtained but the other effect can be obtained. FIG. 6 shows a brief configuration and a functional block diagram of the electric power control device 140 according to the modification example.

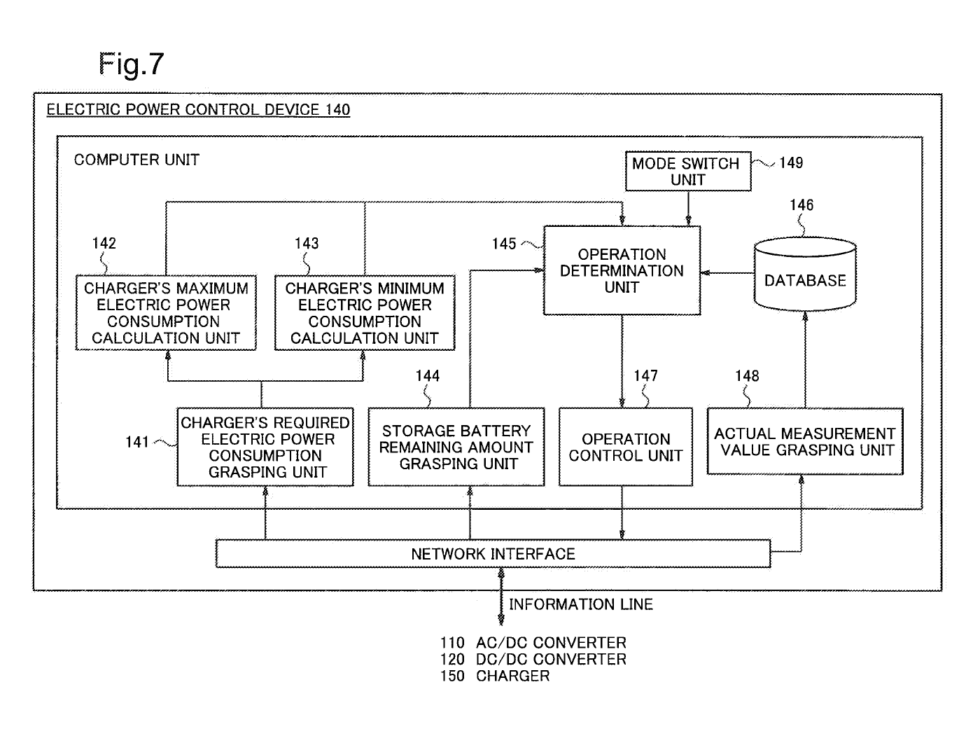

3. In the conventional technology, a rated control in which the storage battery is charged and discharged at the rated electric power is used. However, in this exemplary embodiment, a suppression control in which the storage battery is charged and discharged at an electric power smaller than the rated electric power is used in some cases. On the other hand, the electric power control device 140 may include a mode switch unit 149 so that the control can be performed both in a rated control mode and in a suppression control mode. FIG. 7 shows a brief configuration and a functional block diagram of the electric power control device 140 according to a modification example.

4. In the exemplary embodiment, the charging system for charging an electric vehicle has been described above. However, the charged object is not limited to the electric vehicle in a case where a range between the maximum electric power consumption and the minimum electric power consumption of the charger 150 is a fixed range and stable. For example, the charging system can be used for charging an electrically-driven robot or the like.

—Supplementary Note—

A part of or all of the above-mentioned exemplary embodiment can be described as the following supplementary note. However, the present invention is not limited to the following supplementary note.

The present invention is the charging system equipped with the charger 150, the AC/DC converter 110, the DC/DC converter 120, the storage battery 130, and the control device 140. The control device 140 includes the charger's required electric power consumption grasping unit 141 which grasps the required electric power consumption of the charger, the charger's maximum electric power consumption calculation unit 142 which calculates the maximum electric power consumption of the charger based on the required electric power consumption, the charger's minimum electric power consumption calculation unit 143 which calculates the minimum electric power consumption of the charger based on the required electric power consumption, the storage battery remaining capacity grasping unit 144 which grasps the remaining capacity of the storage battery, the operation combination determination unit 145 which determines the combination of the operations of the charger, the AC/DC converter, and the DC/DC converter based on the remaining capacity of the storage battery so that the electric power loss of the entire charging system is minimum when the electric power consumption of the charger is between the charger's maximum electric power consumption and the charger's minimum electric power consumption, and the operation control unit 147 which operates the charger, the AC/DC converter, and the DC/DC converter based on the combination.

In the charging system of the present invention, it is further preferable that the above-mentioned control device 140 further includes a combination storage unit 146 which stores the set of the combinations and the operation combination determination unit 145 refers to the set of the combinations and determines the combination of the operations.

In the charging system of the present invention, it is further preferable that the above-mentioned control device 140 further includes the actual measurement value grasping unit 148 which grasps the actual measurement value that is a result of the operations of the charger, the AC/DC converter, and the DC/DC converter and the above-mentioned combination storage unit 146 rewrites the set of the combinations based on the actual measurement value.

In the charging system of the present invention, it is further preferable that the above-mentioned control device 140 further includes the mode switch unit 149 which performs the switching of the control mode between a rated control mode in which the AC/DC converter operates so as to charge and discharge the storage battery at the rated electric power and a suppression control mode in which the AC/DC converter operates so as to charge and discharge the storage battery at an electric power smaller than the rated electric power.

In the charging system of the present invention, it is further preferable that the above-mentioned operation combination determination unit 145 determines the combination with which the AC/DC converter operates so as to discharge the storage battery at an electric power smaller than the rated electric power.

In the charging system of the present invention, it is further preferable that the operation combination determination unit 145 determines the combination with which the AC/DC converter operates so as to charge the storage battery at an electric power smaller than the rated electric power.

In the charging system of the present invention, it is further preferable that the charger's required electric power consumption grasping unit 141 grasps the required electric power consumption based on the required electric power amount of the charger and the requested charging time.

The present invention is a method for controlling the charging system equipped with the charger 150, the AC/DC converter 110, the storage battery 130, the DC/DC converter 120, and the control device 140. Wherein the above-mentioned control device 140 grasps the required electric power consumption of the charger (S110), calculates the maximum electric power consumption of the charger based on the required electric power consumption, calculates the minimum electric power consumption of the charger based on the required electric power consumption (S120), grasps the remaining capacity of the storage battery (S130), determines the combination of the operations of the charger, the AC/DC converter, and the DC/DC converter based on the remaining capacity of the storage battery so that the electric power loss of the entire charging system is minimum when the electric power consumption of the charger is between the maximum electric power consumption and the minimum electric power consumption (S150), and operates the charger, the AC/DC converter, and the DC/DC converter based on the combination (S160).

In the charging system control method of the present invention, it is further preferable that the combination storage unit 146 which stores the set of the combinations is referred to (S140) and the set of combinations of the operations is determined (S150).

In the charging system control method of the present invention, it is further preferable that an actual measurement value that is a result of the operations of the charger, the AC/DC converter, and the DC/DC converter is grasped (S170) and the set of the combinations is rewritten based on the actual measurement value (S180).

In the charging system control method of the present invention, it is further preferable that the switching of the control mode is performed between a rated control mode in which the AC/DC converter operates so as to charge and discharge the storage battery at the rated electric power and a suppression control mode in which the AC/DC converter operates so as to charge and discharge the storage battery at an electric power smaller than the rated electric power.

In the charging system control method of the present invention, it is further preferable that the combination with which the AC/DC converter operates so as to discharge the storage battery at an electric power smaller than the rated electric power is determined (S150).

In the charging system control method of the present invention, it is further preferable that the combination with which the AC/DC converter operates so as to charge the storage battery at an electric power smaller than the rated electric power is determined (S150).

In the charging system control method of the present invention, it is further preferable that the required electric power consumption is grasped based on the required electric power amount of the charger and the requested charging time (S110).

The present invention is a control program for controlling the charging system equipped with the charger 150, the AC/DC converter 110, the storage battery 130, the DC/DC converter 120, and the control device 140. The control program causes the control device 140 to perform a charger's required electric power consumption grasping process in which the required electric power consumption of the charger is grasped (S110), a charger's maximum electric power consumption calculation process in which the maximum electric power consumption of the charger is calculated based on the required electric power consumption and the charger's minimum electric power consumption calculation process in which the minimum electric power consumption of the charger is calculated based on the required electric power consumption (S120), a storage battery remaining capacity grasping process in which a remaining capacity of the storage battery is grasped (S130), an operation combination determination process in which the combination of the operations of the charger, the AC/DC converter, and the DC/DC converter is determined based on the remaining capacity of the storage battery so that the electric power loss of the entire charging system is minimum when the electric power consumption of the charger is between the charger's maximum electric power consumption and the charger's minimum electric power consumption (S150), and an operation control process in which the charger, the AC/DC converter, and the DC/DC converter are operated based on the combination (S160).

In the control program which controls the charging system of the present invention, it is further preferable that a database reference process (S140) in which the combination storage unit 146 which stores the set of the combinations is referred to is performed and the operation combination determination process (S150) is performed.

In the control program which controls the charging system, it is further preferable that an actual measurement value grasping process in which an actual measurement value that is a result of the operations of the charger, the AC/DC converter, and the DC/DC converter is grasped (S170) and a database rewrite process in which the set of the combinations is written based on the actual measurement value (S180) are performed.

In the control program which controls the charging system, it is further preferable that a mode switch process in which the switching of the control mode is performed between a rated control mode in which the AC/DC converter operates so as to charge and discharge the storage battery at the rated electric power and a suppression control mode in which the AC/DC converter operates so as to charge and discharge the storage battery at an electric power smaller than the rated electric power is performed.

In the operation combination determination process (S150) of the control program which controls the charging system, it is further preferable that the combination with which the AC/DC converter operates so as to discharge the storage battery at an electric power smaller than the rated electric power is determined.

In the operation combination determination process (S150) of the control program which controls the charging system, it is further preferable that the combination with which the AC/DC converter operates so as to charge the storage battery at an electric power smaller than the rated electric power is determined.

In the charger's required electric power consumption grasping process (S110) of the control program which controls the charging system, it is further preferable that the required electric power consumption is grasped based on the required electric power amount of the charger and the requested charging time.

This application claims priority based on Japanese Patent Application No. 2012-126287 filed on Jun. 1, 2012, the disclosure of which is hereby incorporated by reference in its entirety.

### REFERENCE SIGNS LIST

100 charging system
110 AC/DC converter
120 DC/DC converter
130 storage battery
140 electric power control device
141 charger's required electric power consumption grasping unit
142 charger's maximum electric power consumption calculation unit
143 charger's minimum electric power consumption calculation unit
144 storage battery remaining amount grasping unit
145 operation combination determination unit
146 database
147 operation control unit
148 actual measurement value grasping unit
149 mode switch unit
150 charger

1. A charging system including a charger, an AC/DC converter, a DC/DC converter, a storage battery and a control device, wherein
the control device comprises:
a charger's required electric power consumption grasping unit that grasps a required electric power consumption of the charger;
a charger's maximum electric power consumption calculation unit that calculates a maximum electric power consumption of the charger based on the required electric power consumption;
a charger's minimum electric power consumption calculation unit that calculates a minimum electric power consumption of the charger based on the required electric power consumption;
a storage battery remaining capacity grasping unit that grasps a remaining capacity of the storage battery;
an operation combination determination unit that determines a combination of operations of the charger, the AC/DC converter, and the DC/DC converter based on the remaining capacity of the storage battery so that an electric power loss of the entire charging system is minimum when the electric power consumption of the charger is between the charger's maximum electric power consumption and the charger's minimum electric power consumption; and
an operation control unit that operates the charger, the AC/DC converter, and the DC/DC converter based on the combination.

2. The charging system according to claim 1, wherein
the control device further comprises a combination storage unit which stores a set of the combinations and
the operation combination determination unit refers to the set of the combinations and determines the combination of operations.

3. The charging system according to claim 2, wherein
the control device further comprises an actual measurement value grasping unit which grasps an actual measurement value that is a result of the operations of the charger, the AC/DC converter, and the DC/DC converter, and
the combination storage unit rewrites the set of the combinations based on the actual measurement value.

4. The charging system according to claim 1, wherein
the control device comprises
a mode switch unit that performs switching of a control mode between a rated control mode in which the AC/DC converter operates so as to charge and discharge the storage battery at a rated electric power and a suppression control mode in which the AC/DC converter operates so as to charge and discharge the storage battery at an electric power smaller than the rated electric power.

5. The charging system according to claim 1, wherein
the operation combination determination unit determines the combination with which the AC/DC converter operates so as to discharge the storage battery at an electric power smaller than the rated electric power.

6. The charging system according to claim 1, wherein
the operation combination determination unit determines the combination with which the AC/DC converter operates so as to charge the storage battery at an electric power smaller than the rated electric power.

7. The charging system according to claim 1, wherein
the charger's required electric power consumption grasping unit grasps the required electric power consumption based on a required electric power amount of the charger and a requested charging time.

8. A method for controlling a charging system including a charger, an AC/DC converter, a storage battery, a DC/DC converter and a control device, wherein
the control device
grasps a required electric power consumption of the charger,
calculates a maximum electric power consumption of the charger based on the required electric power consumption,
calculates a minimum electric power consumption of the charger based on the required electric power consumption,
grasps a remaining capacity of the storage battery,
determines a combination of operations of the charger, the AC/DC converter, and the DC/DC converter based on the remaining capacity of the storage battery so that an electric power loss of the entire charging system is minimum when an electric power consumption of the charger is between the charger's maximum electric power consumption and the charger's minimum electric power consumption, and
operates the charger, the AC/DC converter, and the DC/DC converter based on the combination.

9. A non-transitory computer-readable storage medium storing a control program for controlling a charging system including a charger, an AC/DC converter, a storage battery, a DC/DC converter and a control device, wherein the control program causes the control device to perform:
a charger's required electric power consumption grasping processing in which a required electric power consumption of the charger is grasped;
a charger's maximum electric power consumption calculation processing in which a maximum electric power consumption of the charger is calculated based on the required electric power consumption;
a charger's minimum electric power consumption calculation processing in which a minimum electric power consumption of the charger is calculated based on the required electric power consumption;
a storage battery remaining capacity grasping process in which a remaining capacity of the storage battery is grasped;
an operation combination determination processing in which a combination of operations of the charger, the AC/DC converter, and the DC/DC converter is determined based on the remaining capacity of the storage battery so that an electric power loss of the entire charging system is minimum when an electric power consumption of the charger is between the charger's maximum electric power consumption and the charger's minimum electric power consumption; and
an operation control processing in which the charger, the AC/DC converter, and the DC/DC converter are operated based on the combination.
